(19) United States
(12) Patent Application Publication
(10) Pub. No.: US 2015/0167161 A1
(43) Pub. Date: Jun. 18, 2015

(54) GAS INJECTION COMPONENTS FOR DEPOSITION SYSTEMS AND RELATED METHODS

(71) Applicant: Soitec, Bemin (FR)

(72) Inventors: Claudio Canizares, Chandler, AZ (US); Dan Gura, Chandler, AZ (US); Ronald Thomas Bertram, JR., Mesa, AZ (US)

(73) Assignee: Soitec, Bernin (FR)

(21) Appl. No.: 14/401,352

(22) PCT Filed: May 24, 2013
(86) PCT No.: PCT/IB2013/001054

§ 371 Date: Nov. 14, 2014

Related U.S. Application Data
(60) Provisional application No. 61/656,846, filed on Jun. 7, 2012.

(51) Int. Cl. C23C 16/455

(52) U.S. Cl. CPC C23C 16/455

(57) ABSTRACT

A gas injector includes a base plate, a middle plate, and a top plate. The base plate, middle plate, and top plate are configured to flow a purge gas between the base plate and the middle plate and to flow a precursor gas between the middle plate and the top plate. Another gas injector includes a precursor gas inlet, a lateral precursor gas flow channel, and a plurality of precursor gas flow channels. The plurality of precursor gas flow channels extend from the at least one lateral precursor gas flow channel to an outlet of the gas injector. Methods of forming a material on a substrate include flowing a precursor between a middle plate and a top plate of a gas injector and flowing a purge gas between a base plate and the middle plate of the gas injector.

### CROSS-REFERENCE TO RELATED APPLICATIONS

This application is a national phase entry under 35 U.S.C. §371 of International Patent Application PCT/IB2013/001054, filed May 24, 2013, designating the United States of America and published in English as International Patent Publication WO2013/182879 A2 on Dec. 12, 2013, which claims the benefit under Article 8 of the Patent Cooperation Treaty to the U.S. Provisional Application Ser. No. 61/656,846, filed Jun. 7, 2012, the disclosure of each of which is hereby incorporated herein in its entirety by this reference.

### TECHNICAL FIELD

The present disclosure relates to gas injection components, such as gas injectors, for injecting gases into a chemical deposition chamber of a deposition system, as well as to systems including such components and methods of forming material on a substrate using such components and systems.

### BACKGROUND

Semiconductor structures are structures that are used or formed in the fabrication of semiconductor devices. Semiconductor devices include, for example, electronic signal processors, electronic memory devices, photoactive devices (e.g., light emitting diodes (LEDs), photovoltaic (PV) devices, etc.), and microelectromechanical (MEM) devices. Such structures and materials often include one or more semiconductor materials (e.g., silicon, germanium, silicon carbide, a III-V semiconductor material, etc.), and may include at least a portion of an integrated circuit.

Semiconductor materials formed of a combination of elements from Group III and Group V on the periodic table of elements are referred to as III-V semiconductor materials. Example III-V semiconductor materials include Group III-nitride materials, such as gallium nitride (GaN), aluminum nitride (AlN), aluminum gallium nitride (AlGaN), indium nitride (InN), and indium gallium nitride (InGaN). Hydride vapor phase epitaxty (HVPE) is a chemical vapor deposition (CVD) technique used to form (e.g., grow) Group III-nitride materials on a substrate.

In an example HVPE process for forming GaN, a substrate comprising silicon carbide (SiC) or aluminum oxide (Al₂O₃, often referred to as “sapphire”) is placed in a chemical deposition chamber and heated to an elevated temperature. Chemical precursors of gallium chloride (e.g., GaCl, GaCl₃) and ammonia (NH₃) are mixed within the chamber and react to form GaN, which epitaxially grows on the substrate to form a layer of GaN. One or more of the precursors may be formed within the chamber (i.e., in situ), such as when GaCl is formed by flowing hydrochloric acid (HCl) vapor across molten gallium, or one or more of the precursors may be formed prior to injection into the chamber (i.e., ex situ).

In prior known configurations, the precursor GaCl may be injected into the chamber through a generally planar gas injector having diverging internal sidewalls (often referred to as a “visor” or “visor injector”). The precursor NH₃ may be injected into the chamber through a multi-port injector. Upon injection into the chamber, the precursors are initially separated by a top plate of the visor injector that extends to a location proximate an edge of the substrate. When the precursors reach the end of the top plate, the precursors mix and react to form a layer of GaN material on the substrate.

### BRIEF SUMMARY

This summary is provided to introduce a selection of concepts in a simplified form. These concepts are described in further detail in the detailed description of example embodiments of the disclosure below. This summary is not intended to identify key features or essential features of the claimed subject matter, nor is it intended to be used to limit the scope of the claimed subject matter.

In some embodiments, the present disclosure includes gas injectors for a chemical deposition chamber that include a base plate, a middle plate positioned over the base plate, and a top plate positioned over the middle plate on a side thereof opposite the base plate. The base plate, middle plate, and top plate are configured to flow a purge gas between the base plate and middle plate and to flow a precursor gas between the middle plate and the top plate.

In other embodiments, the present disclosure includes gas injectors for a chemical deposition chamber that include a precursor gas inlet, at least one lateral precursor gas flow channel in fluid communication with the precursor gas inlet, and a plurality of precursor gas flow channels in fluid communication with the at least one lateral precursor gas flow channel. The plurality of precursor gas flow channels extend from the at least one lateral precursor gas flow channel to an outlet of the gas injector.

In some embodiments, the present disclosure includes methods of forming a material on a substrate. In accordance with such methods, a first precursor gas is flowed between a middle plate and a top plate of a gas injector. A purge gas is flowed between a base plate and the middle plate of the gas injector. The first precursor gas is flowed out of the gas injector and toward a substrate positioned proximate the visor injector.

### BRIEF DESCRIPTION OF THE DRAWINGS

While the specification concludes with claims particularly pointing out and distinctly claiming what are regarded as embodiments of the invention, the advantages of embodiments of the disclosure may be more readily ascertained from the description of certain examples of embodiments of the disclosure when read in conjunction with the accompanying drawings, in which:

FIG. 1 is simplified schematic view of a base plate of a gas injector of a chemical deposition chamber showing precursor gas flow and purge gas flow;

FIG. 2 illustrates the base plate of FIG. 1 with a leak between a central chamber and a purge gas channel thereof;

FIG. 3 is an exploded perspective view of a gas injector according to an embodiment of the present disclosure including a base plate, a middle plate, and a top plate;

FIG. 4 is a top view of the base plate of FIG. 3;

FIG. 5 is a top view of the top plate of FIG. 3;

FIG. 6 is a bottom view of the middle plate of FIG. 3 showing purge gas flow channels formed therein;

FIG. 7 is a top view of the middle plate of FIG. 3 showing precursor gas flow channels formed therein;

FIG. 8 is a partial cross-sectional view of a portion of the gas injector of FIG. 3 when assembled, including the base plate, the middle plate, the top plate, and a weld coupling the middle plate to the top plate along peripheral edges of the middle plate and top plate;

FIG. 9 illustrates gas flow through the gas injector of FIG. 3; and

FIG. 10 is a graph developed from a computer model and simulation showing average precursor mass flow through the gas injector of FIG. 3 during a deposition process.

### DETAILED DESCRIPTION

The illustrations presented herein are not meant to be actual views of any particular material, structure, or device, but are merely idealized representations that are used to describe embodiments of the disclosure.

As used herein, the term “substantially,” in reference to a given parameter, property, or condition, means to a degree that one of ordinary skill in the art would understand that the given parameter, property, or condition is met within a degree of variance, such as within acceptable manufacturing tolerances.

As used herein, any relational term, such as “first,” “second,” “on,” “over,” “under,” “top,” “bottom,” “upper,” “opposite,” etc., is used for clarity and convenience in understanding the disclosure and accompanying drawings and does not connote or depend on any specific preference, orientation, or order, except where the context clearly indicates otherwise.

As used herein, the term “gas” means and includes a fluid that has neither independent shape nor volume. Gases include vapors. Thus, when the terms “gas” is used herein, it may be interpreted as meaning “gas or vapor.”

As used herein, the phrase “gallium chloride” means and includes one or more of gallium monochloride (GaCl) and gallium trichloride, which may exist in monomer form (GaCl₃) or in dimer form (Ga₂Cl₆). For example, gallium chloride may be substantially comprised of gallium monochloride, substantially comprised of gallium trichloride, or substantially comprised of both gallium monochloride and gallium trichloride.

The present disclosure includes structures and methods that may be used to flow gas toward a substrate, such as to deposit or otherwise form a material (e.g., a semiconductor material, a III-V semiconductor material, a gallium nitride (GaN) material, a silicon carbide material, etc.) on a surface of the substrate. In particular embodiments, the present disclosure relates to gas injectors and components thereof, deposition systems using such gas injectors, methods of depositing or otherwise forming a material on a substrate using such gas injectors, and methods of flowing gases through such gas injectors. In some embodiments, the gas injectors of the present disclosure may include a base plate, a middle plate, and a top plate, with a weld sealing at least one peripheral outer edge of the middle plate to at least one corresponding peripheral outer edge of the top plate. In some embodiments, the gas injectors of the present disclosure may include a plurality of precursor gas flow channels for flowing a precursor gas from a precursor gas inlet to an outlet side of the gas injectors. Examples of such structures and methods are disclosed in further detail below.

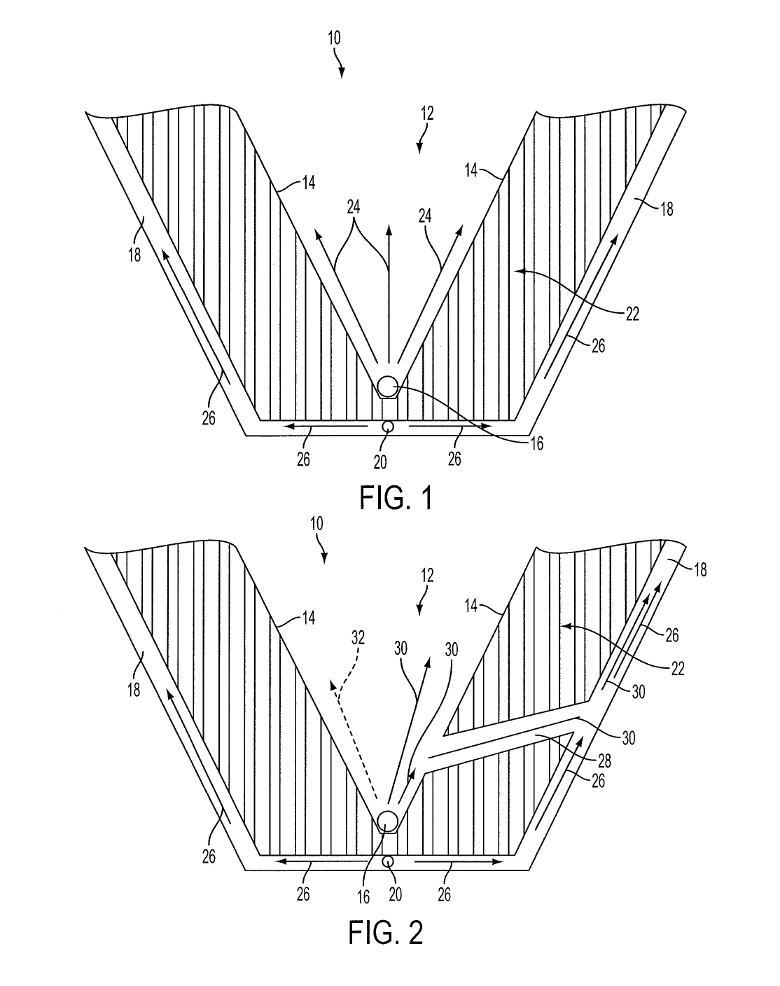

FIG. 1 illustrates a schematic view of a base plate 10 of a gas injector for a chemical deposition chamber (e.g., an HVPE deposition chamber) of a deposition system and includes features formed therein for flowing a precursor gas and a purge gas through the base plate 10. For example, the base plate 10 may include a central chamber 12 with diverging sidewalls 14 for flowing a precursor gas (e.g., a gallium chloride (e.g., GaCl, GaCl₃) gas) from a precursor gas inlet 16 toward a substrate (not shown) on which a material (e.g., a III-V semiconductor material, a GaN material, etc.) is to be formed through a chemical deposition process (e.g., a chemical vapor deposition process, an HVPE process, etc.). The base plate 10 may also include purge gas channels 18 for flowing purge gases (e.g., H₂, N₂, SiH₄, HCl, etc.) from a purge gas inlet 20 into the chemical deposition chamber. The purge gas channels 18 may be positioned laterally outside of and adjacent to the central chamber 12. The base plate 10 may also include a sealing surface 22 between the central chamber 12 and the purge gas channels 18.

A top plate (not shown) may be positioned over the base plate 10 and may abut against the base plate 10 at the sealing surface 22. Ideally, a seal may be formed between the sealing surface 22 and the top plate to separate the central chamber 12 from the purge channel 18 and to inhibit precursor gas and/or purge gas from flowing across the sealing surface 22. As shown by arrows 24 in FIG. 1, precursor gas ideally flows from the precursor gas inlet 16 toward the substrate through the central chamber 12 and is relatively evenly distributed across the width of the central chamber 12. During operation, the precursor gas (e.g., gallium chloride) flowing through the central chamber 12 of the base plate 10 may be separated from another precursor gas (e.g., NH₃) by the top plate. After the precursor gases reach an end of the top plate proximate a substrate, the precursor gases may mix and react to form a material comprising at least portions of each of the precursor gases (e.g., a GaN material comprising Ga from the gallium chloride precursor and N from the NH₃ precursor) on the substrate. As shown by arrows 26 in FIG. 1, purge gas ideally flows from the purge gas inlet 20 toward the chemical deposition chamber through the purge gas channels 18. During operation, the purge gas flowing through the purge gas channels 18 may be flowed prior to or after flowing the precursor gases, such as to purge the chemical deposition chamber of unwanted chemicals. The purge gas may alternatively or additionally be flowed while flowing the precursor gases, such as to act as a carrier gas for carrying byproducts of the chemical deposition process (e.g., HCl) out of the chemical deposition chamber. The purge gas may be directed along sidewalls of the chemical deposition chamber to act as a gas curtain for limiting parasitic deposition of material from the precursor gases on the sidewalls of the deposition chamber.

Although the present disclosure describes, as an example, flowing gallium chloride and NH₃ in the chemical deposition chamber to form GaN on the substrate, the present disclosure is also applicable to flowing other gases, such as to form materials other than GaN (e.g., AlN, AlGaN, InN, InGaN, etc.). Indeed, one of ordinary skill in the art will recognize that the structures and methods of the present disclosure, as well as components and elements thereof, may be used in many applications that involve flowing one or more gases into and through a chemical deposition chamber.

Referring to FIG. 2, a leak 28 between the sealing surface 22 of the base plate 10 and a surface of the top plate abutting against the sealing surface 22 may be present due to imperfections in the sealing surface 22 and/or the surface of the top plate. Imperfections may be present at formation of the base plate 10 and/or of the top plate, or may result from subsequent acts. By way of example and not limitation, the base plate 10 may comprise quartz that is fire polished to enable a body of the base plate 10 to endure high heat and low pressures expected during operation. In some embodiments, the base plate 10 may be fire polished multiple times during its life. Such fire polishing may cause the sealing surface 22 to warp or otherwise be deformed, resulting in the leak 28.

Some precursor gas may flow through the leak 28, which may modify flow of the precursor gas through the central chamber 12. For example, the precursor gas may flow through the leak 28 and along the sidewall 14 proximate the leak 28, as shown by arrows 30 in FIG. 2. However, relatively little or no precursor gas may flow along the sidewall 14 distant from the leak, as shown by the dashed arrow 32 in FIG. 2. Therefore, the leak 28 may result in a non-uniform distribution of precursor gas flow through the central chamber 12 and across the substrate, which, in turn, may result in a non-uniform thickness of material (e.g., GaN) formed on the substrate from the precursor gas. In addition, the portion of the precursor gas flowing through the leak 28 and purge channel 18 may not flow over a central region of the substrate, and an average thickness of the material formed on the substrate may be reduced for a given time and/or precursor gas flow rate. To counteract the effects of the leak 28, more time and/or more precursor gas may be required to form a desired thickness of material on the substrate, which adds to production costs. Furthermore, the leak 28 may reduce the controllability and predictability of the gas flows through the chemical deposition chamber, as well as of the process of forming the material on the substrate. The leak 28 may also affect the efficiency of the chemical deposition process, since a portion of the precursor gas flows through the leak 28 and away from the substrate. Thus, the amount and cost of precursor gas used to form a desired amount of material on the substrate increases due to the leak 28.

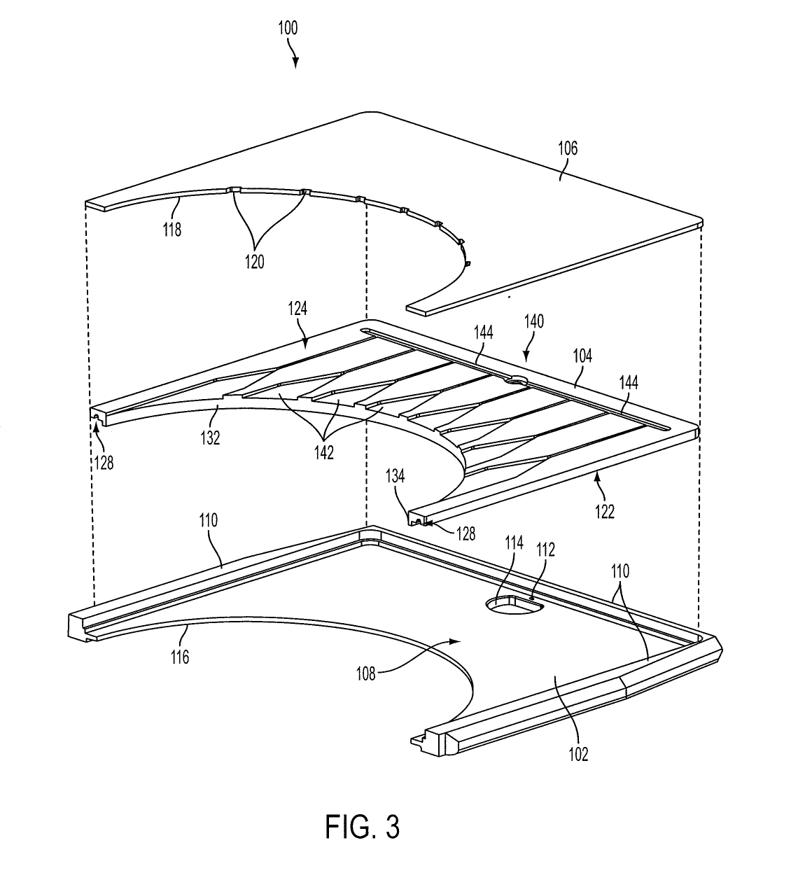

FIG. 3 illustrates an exploded perspective view of a gas injector 100 according to an embodiment of the present disclosure. The gas injector 100 may include a base plate 102, a middle plate 104 over the base plate 102, and a top plate 106 over the middle plate 104. The gas injector 100 may be configured to inject one or more of a precursor gas and a purge gas into a chemical deposition chamber (e.g., an HVPE deposition chamber) for forming a material on a substrate (not shown) positioned proximate the gas injector 100. During operation, the precursor gas may be heated prior to injection into the chemical deposition chamber through the gas injector 100. One method of heating a gallium chloride precursor gas prior to injection into the chemical deposition chamber is disclosed in International Publication No. WO 2010/101715 A1, filed Feb. 17, 2010 and titled “GAS INJECTORS FOR CVD SYSTEMS WITH THE SAME,” the disclosure of which is incorporated herein in its entirety by this reference. The precursor gas may be preheated to more than about 500° C. In some embodiments, the precursors may be preheated to more than about 650° C., such as between about 700° C. and about 800° C. Prior to being heated, a gallium chloride precursor may be substantially comprised of gallium trichloride, which may exist in monomer form (GaCl₃) or in dimer form (Ga₂Cl₆). Upon heating and/or injection into the chemical deposition chamber, at least a portion of the GaCl₃ may thermally decompose into gallium monochloride (GaCl) and other byproducts, for example. Thus, in the chemical deposition chamber, the gallium chloride precursor may be substantially comprised of GaCl, although some GaCl₃ may also be present. In addition, the substrate may also be heated prior to injection of the precursor gas, such as to more than about 500° C. In some embodiments, the substrate may be preheated to a temperature between about 900° C. and about 1000° C.

The substrate may comprise any material on which GaN or another desired material (e.g., another III-V semiconductor material) may be formed (e.g., grown, epitaxially grown, deposited, etc.). For example, the substrate may comprise one or more of silicon carbide (SiC) and aluminum oxide (Al₂O₃, often referred to as “sapphire”). The substrate may be a single, so-called “wafer” of material on which the GaN is to be formed, or it may be a susceptor (e.g., a SiC-coated graphite susceptor) for holding multiple smaller substrates of material on which the GaN is to be formed.

The components of the gas injector 100, including the base plate 102, middle plate 104, and top plate 106, may each be formed of any material that can sufficiently maintain its shape under operating conditions (e.g., chemicals, temperatures, flow rates, pressures, etc.). Additionally, the material of the components of the gas injector 100 may be selected to inhibit reaction with gas (e.g., a precursor) flowing through the gas injector 100. By way of example and not limitation, one or more of the components may be formed of one or more of a metal, a ceramic, and a polymer. In some embodiments, one or more of the components may be at least substantially comprised of quartz, such as clear fused quartz that is fire polished, for example. In some embodiments, one or more of the components may comprise a SiC material. One or more of the components may be cleaned to reduce contaminants in the chemical deposition chamber, such as with a 10% hydrofluoric (HF) acid solution, followed by a rinse with distilled and/or deionized water, for example.

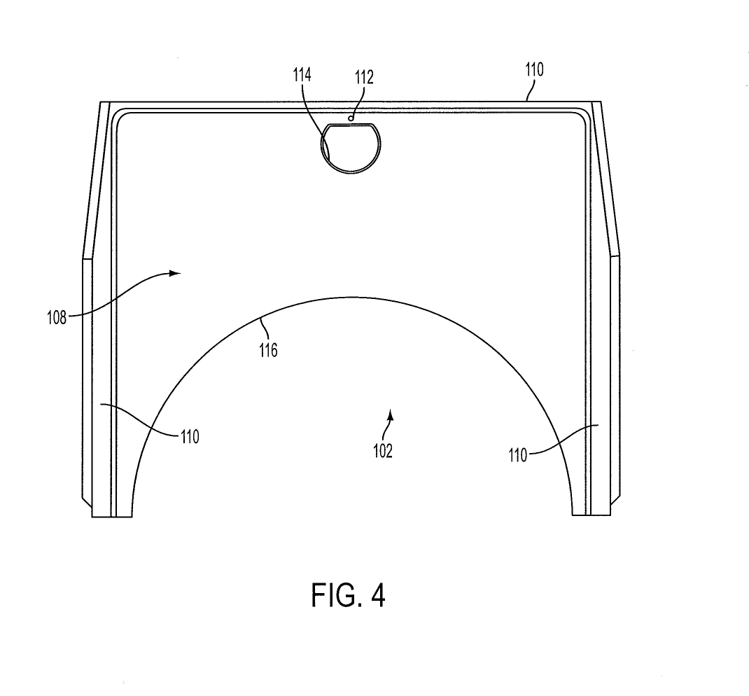

Referring to FIG. 4 in conjunction with FIG. 3, the base plate 102 may have a substantially flat upper surface 108. Sidewalls 110 may extend from the upper surface 108 and along peripheral edges of the base plate 102. A purge gas inlet 112 may extend through the base plate 102, the purge gas inlet 112 sized and configured to enable purge gas to be flowed through the purge gas inlet 112 from an exterior of the chemical deposition chamber. A hole 114 may also extend through the base plate 102, the hole 114 sized and configured to receive a precursor gas inlet stem of the middle plate 104, as will be explained in more detail below. An outlet side 116 of the base plate 102 may be at least partially defined by a generally semicircular surface sized and configured to be positioned proximate a substrate on which material is to be formed.

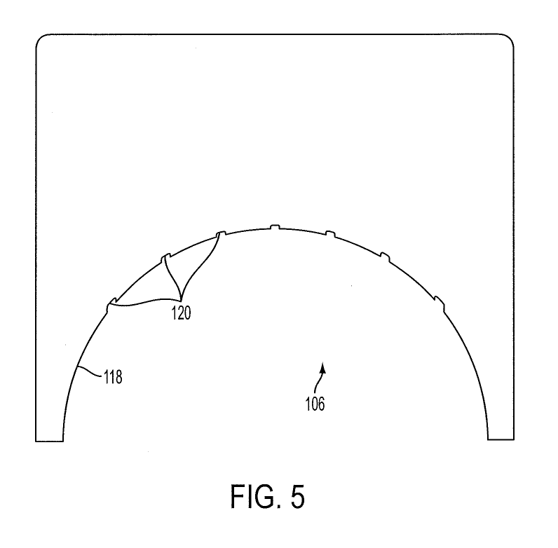

Referring to FIG. 5 in conjunction with FIG. 3, the top plate 106 may be a substantially flat member sized and configured to be assembled with the base plate 102 and middle plate 104. In some embodiments, the top plate 106 may be sized and configured to fit over the middle plate 104 and at least partially within the sidewalls 110 of the base plate 102. The top plate 106 may have an outlet side 118 that is at least partially defined by a generally semicircular surface sized and configured to be positioned proximate a substrate on which material is to be formed. In operation, a first precursor gas (e.g., gallium chloride) may be flowed along a bottom surface of the top plate 106, and a second precursor gas (e.g., NH₃) may be flowed along an upper surface of the top plate 106. As the first and second precursor gases reach the outlet side 118 of the top plate 106, the first and second precursor gases may mix and react to form (e.g., grow, epitaxially grow, deposit, etc.) a material on a substrate positioned proximate to the outlet side 118. Notches 120 may be formed along the outlet side 118 of the top plate 106 to facilitate the formation of welds between the top plate 106 and the middle plate 104 at the notches 120.

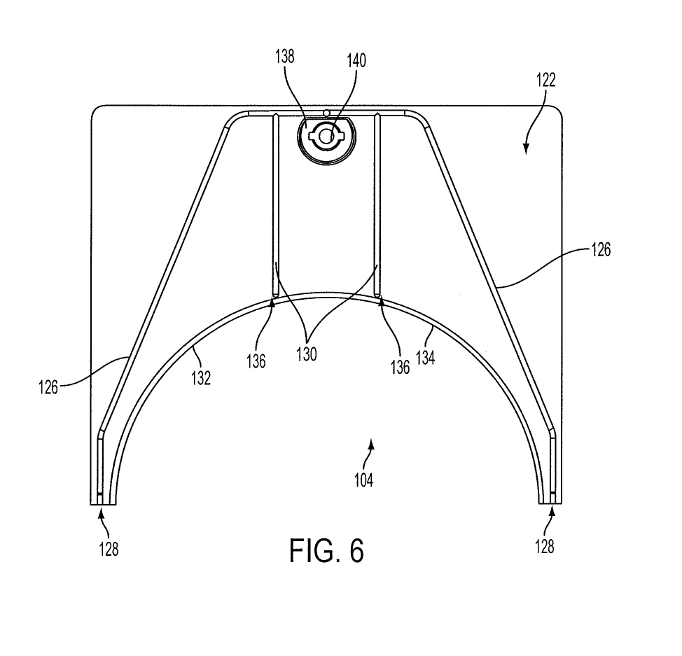

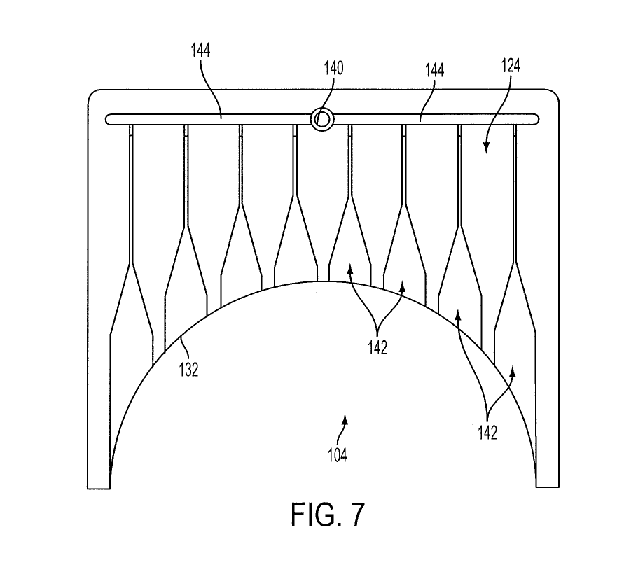

Referring to FIGS. 6 and 7 in conjunction with FIG. 3, the middle plate 104 may have a bottom surface 122 (FIG. 6) in which one or more features for flowing purge gas are formed and an upper surface 124 (FIG. 7) in which one or more features for flowing precursor gas are formed. As shown in FIG. 6, for example, purge gas flow channels 126 may be formed in the bottom surface 122 such that purge gas may flow from the purge gas inlet 112 of the base plate 102 (FIGS. 3 and 4) to purge gas outlets 128. Thus, the purge gas flow channels 126 may be in fluid communication with the purge gas inlet 112 of the base plate 102 (FIGS. 3 and 4) when the middle plate 104 is assembled with the base plate 102. Optionally, centrally located purge gas channels 130 may also be formed in the bottom surface 122 of the middle plate 104, if purge gas is to be flowed from a central region of the gas injector 100. The middle plate 104 may have an outlet side 132 that is at least partially defined by a generally semicircular surface sized and configured to be positioned proximate a substrate on which material is to be formed. A lip 134 may extend from the bottom surface 122 along the outlet side 132. When assembled with the base plate 102, the lip 134 of the middle plate 104 may hang and extend over the generally semicircular outlet side 116 of the base plate 102. As can be seen in FIG. 6, the centrally located purge gas channels 130 may have outlets 136 proximate to, but not through, the lip 134. Accordingly, during operation, purge gas flowing through the centrally located purge gas channels 130 may be directed by the lip 134 to flow across a bottom surface of the precursor located proximate to the outlet side 132 of the middle plate 104.

As shown in FIG. 6, a precursor gas inlet stem 138 may extend from the bottom surface 122 of the middle plate 104. The precursor gas inlet stem 138 may be sized and configured to be disposed at least partially within (e.g., to extend through) the hole 114 in the base plate 102 (FIGS. 3 and 4). A precursor inlet 140 (i.e., a hole) may extend through the precursor gas inlet stem 138 to provide fluid communication to the upper surface 124 of the middle plate 104. The middle plate 104 may be sized and configured for assembly with the base plate 102 and the top plate 106 to form the gas injector 100. For example, the middle plate 104 may fit at least partially inside the sidewalls 110 (FIGS. 3 and 4) of the base plate 102 and substantially entirely under the top plate 106 when assembled therewith.

Referring to FIG. 7 in conjunction with FIG. 3, the upper surface 124 of the middle plate 104 may include one or more features for flowing precursor gas from the precursor inlet 140 to the outlet side 132 of the middle plate 104, and ultimately over a substrate positioned proximate to the gas injector 100. For example, as shown in FIGS. 3 and 7, a plurality of precursor gas flow channels 142 may be formed in the upper surface 124 of the middle plate 104. At least one lateral precursor gas flow channel 144 may provide fluid communication between the precursor inlet 140 and each of the precursor gas flow channels 142. As shown in FIGS. 3 and 7, the at least one lateral precursor gas flow channel 144 may extend in a direction at least substantially perpendicular to a direction in which the plurality of precursor gas flow channels 142 extend. In some embodiments, each of the precursor gas flow channels 142 may be relatively narrow at the at least one lateral precursor gas flow channel 144 and relatively wide at the outlet side 132 of the middle plate 104, as shown in FIGS. 3 and 7. In some embodiments, each of the precursor gas flow channels 142 may be defined by a relatively narrow inlet portion, a relatively wide outlet portion, and a diverging intermediate portion between the inlet portion and the outlet portion, as shown in FIGS. 3 and 7.

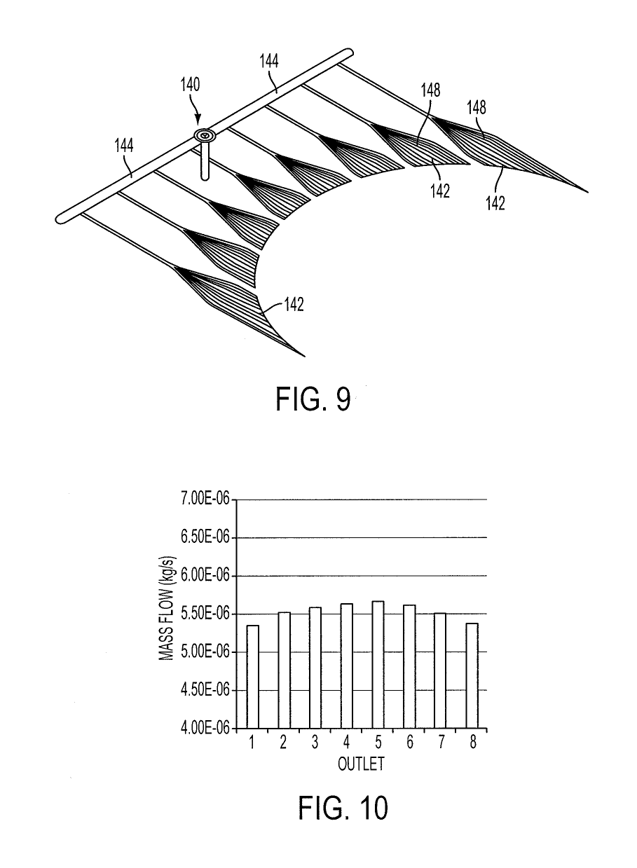

The plurality of precursor gas flow channels 142 may enable improved distribution of precursor gas across a substrate. For example, precursor gas may be more uniformly distributed across the outlet side 132 of the middle plate 104, and ultimately across the substrate, as described below with reference to FIGS. 9 and 10. In addition, the precursor gas flow channels 142 may be positioned across a wider extent of the outlet side 132 of the middle plate 104 compared to prior known configurations including a single central channel for flowing precursor gas. Thus, a greater portion of the substrate may have the precursor gas flowing thereover and a greater portion of the substrate may have material (e.g., GaN) formed thereon. Furthermore, the plurality of precursor gas flow channels 142 may be used with a gas injector 100 sized for formation of material on a relatively larger substrate. Thus, the design of the precursor gas flow channels 142 may be applicable to gas injectors and substrates of various sizes and configurations.

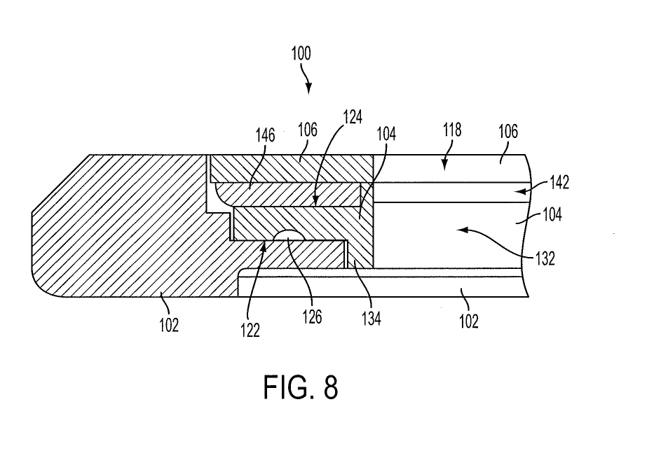

Referring to FIG. 8, a partial cross-sectional view of a portion of the gas injector 100 is shown when assembled. A weld 146 may be formed along at least one peripheral outer edge of the middle plate 104 and top plate 106 to couple the middle plate 104 to the top plate 106. The weld 146 may be formed at least substantially continuously along all the peripheral outer edges of the middle plate 104 and top plate 106 with the exception of along the outlet side 118 of the top plate 106 and the outlet side 132 of the middle plate 104. The weld 146 may seal the top plate 106 to the middle plate 104 and may separate the flow of the precursor gas along the upper surface 124 of the middle plate 104 from the flow of the purge gas along the lower surface 122 of the middle plate 104. Thus, the weld 146 may inhibit (e.g., reduce or eliminate) the formation of leaks between the top plate 106 and the middle plate 104, and undesired flows of the precursor gas from the precursor gas flow channels 142 into the purge gas flow channels 126 may also be inhibited. In forming the gas injector 100, the top plate 106 and the middle plate 104 may be welded together prior to being assembled with the base plate 102. By way of example and not limitation, the weld 146 may be formed of quartz that is melted to adhere to the middle plate 104 and to the top plate 106 and that is subsequently solidified. As noted above, in some embodiments, additional welds may be formed between the top plate 106 and the middle plate 104 at the notches 120 formed in the top plate 106 (FIGS. 3 and 5) for mechanical stability.

Referring again to FIG. 8, the weld 146 may be a so-called “cold weld” formed by application of heat from one side of the weld 146 (e.g., a side along the peripheral outer edges of the top plate 106 and middle plate 104). In contrast, a so-called “hot weld” is formed by application of heat from two opposing sides of the weld. Hot welds are generally more mechanically stable than cold welds. Thus, a hot weld is generally used when a weld is expected to be subjected to high mechanical stress, such as from high temperature, high pressure gradients, etc. In prior known configurations, a hot weld may be considered for use between a top plate and a base plate of a gas injector due to expected high mechanical stress in the base plate during operation. However, formation of such a hot weld is difficult or impossible due to the difficulty in accessing two opposing sides of the weld with heat sources sufficient to form the hot weld. On the other hand, a cold weld would not likely be used in prior known configurations due to the expected high mechanical stress in the base plate during operation. For at least these reasons, prior known gas injectors are generally formed of a top plate abutted against a base plate without using any welds. As described above with reference to FIG. 2, such a configuration exhibits a likelihood of leak formation between the top plate and base plate.

Use of the middle plate 104 of the present disclosure may enable the weld 146 to be formed as a cold weld, since the expected mechanical stress in the middle plate 104 and top plate 106 may not be as much as in the base plate, and a cold weld may be expected to withstand the expected mechanical stress in the middle plate 104 and top plate 106. As noted above, the weld 146 may inhibit the formation of leaks.

Although the purge gas flow channels 126 and, optionally, the centrally located purge gas flow channels 130 are described above with reference to FIG. 6 as being formed in the bottom surface 122 of the middle plate 104, the present disclosure is not so limited. Alternatively or in addition, one or more of the purge gas flow channels 126 and the centrally located purge gas flow channels 130 may be formed in the upper surface 108 of the base plate 102. In such configurations, the bottom surface 122 of the middle plate 104 may be substantially flat, or may also include purge gas flow channels formed therein. Similarly, although the precursor gas flow channels 142 and the at least one lateral precursor gas flow channel 144 are described above with reference to FIGS. 3 and 7 as being formed in the upper surface 124 of the middle plate 104, the present disclosure is not so limited. Alternatively or in addition, one or more of the precursor gas flow channels 142 and the at least one lateral precursor gas flow channel 144 may be formed in the top plate 106. In such configurations, the upper surface 124 of the middle plate 104 may be substantially flat, or may also include precursor gas flow channels formed therein. In any case, the formation of leaks between the middle plate and the top plate, which may result in undesired flow of the precursor gas into the purge gas flow channels, may be inhibited by the weld 146, as described above.

Referring to FIG. 9, a computational fluid dynamics (CFD) model of precursor gas flow through the gas injector 100 of FIGS. 3 and 8 is shown. As represented by flow lines 148 in FIG. 9, a precursor gas (e.g., GaCl₃) may flow from the precursor inlet 140, through the at least one lateral precursor gas flow channel 144, and through the plurality of precursor gas flow channels 142.

Referring to FIG. 10, a graph is illustrated showing average precursor mass flows of the precursor gas through each of the precursor gas channels 142 of the middle plate 104 of the gas injector 100. In the graph of FIG. 10, the outlet labeled “1” corresponds to the precursor gas channel 142 in the upper right of FIG. 9, the outlet labeled “2” corresponds to the precursor gas channel 142 adjacent to the outlet labeled “1,” and so forth.

The flow lines 148 of FIG. 9 and the graph of FIG. 10 demonstrate that the precursor gas is relatively uniformly distributed among the precursor gas flow channels 142. Accordingly, it is expected that material formed from the precursor gas on a substrate positioned proximate outlets of the precursor gas flow channels 142 will have a relatively uniform thickness across the substrate.

Although the drawings of the present disclosure include eight precursor gas flow channels 142, the disclosure is not so limited. Any number of precursor gas flow channels 142 may be used. Indeed, one or more benefits of the present disclosure may be realized with a middle plate including a prior known single central chamber (such as the central chamber 12 of FIGS. 1 and 2). For example, the weld 146 and/or the formation of the purge gas flow channels 126 on a bottom surface of the middle plate may inhibit leak formation, as described above.

Although the drawings of the present disclosure include the middle plate 104 with a plurality of precursor gas flow channels 142 formed therein, the disclosure is not so limited. For example, in some embodiments the middle plate 104 may be omitted and both the precursor gas flow channels 142 and the purge gas flow channels 126 may be formed in one or more of a base plate and a top plate. Although such a configuration may preclude the use of a weld and lead to a greater likelihood of leaks, benefits of the plurality of precursor gas flow channels 142 may still be realized when compared to prior known gas injector configurations including a single central chamber for flowing precursor gas. For example, the plurality of gas flow channels 142 may enable more uniform and/or wider precursor gas flow across a substrate when compared to a single central chamber, as described above.

In some embodiments, the present disclosure also includes methods of forming a material (e.g., a semiconductor material, such as a III-V semiconductor material) on a substrate. Referring again to FIGS. 3 through 9, the base plate 102, middle plate 104, and top plate 106 may be assembled as described above to form the gas injector 100, and the assembled gas injector 100 may be positioned within a chemical deposition chamber. A substrate (not shown) may be positioned proximate the gas injector 100. The substrate may be rotated within the chemical deposition chamber. The substrate may be heated to an elevated temperature, such as above about 500° C. In some embodiments, the substrate may be preheated to a temperature between about 900° C. and about 1000° C.

A first precursor gas (e.g., gaseous gallium chloride) may be flowed through the precursor gas inlet 140 and into a space between the middle plate 104 and the top plate 106 defined by the at least one lateral precursor gas flow channel 144 formed in the upper surface 124 of the middle plate 104, as described above. From the at least one lateral precursor gas flow channel 144, the first precursor gas may be flowed through the plurality of precursor gas flow channels 142 toward the substrate positioned proximate the outlet side 132 of the middle plate 104. The velocity of the first precursor gas may be reduced as the first precursor gas expands through the plurality of precursor gas flow channels 142. The first precursor gas may then be flowed toward and over the substrate.

A second precursor gas (e.g., gaseous NH₃) may be injected into the chemical deposition chamber, such as through a multi-port injector known to one of ordinary skill in the art, and flowed along an upper surface of the top plate 106 opposite the first precursor gas and in generally the same direction as the flow of the first precursor gas. One or more purge gases (e.g., H₂, N₂, SiH₄, HCl, etc.) may also be flowed in the chemical deposition chamber, such as through the purge gas flow channels 126 and/or centrally located purge gas flow channels 130 formed in the bottom surface 122 of the middle plate 104, as described above. One or more of the first precursor gas, the second precursor gas, and the purge gas(es) may be heated prior to, upon, and/or after entering the chemical deposition chamber. For example, one or more of the first precursor gas, the second precursor gas, and the purge gas(es) may be preheated to a temperature above about 500° C. In some embodiments, the one or more of the first precursor gas, the second precursor gas, and the purge gas(es) may be preheated to more than about 650° C., such as between about 700° C. and about 800° C.

After the first precursor gas exits the gas injector 100 comprising the base plate 102, the middle plate 104, and the top plate 106, and after the second precursor gas reaches the outlet side 118 of the top plate 118 proximate the substrate, the first and second precursor gases may be mixed to react and to form (e.g., grow, epitaxially grow, deposit, etc.) a material on the substrate. The material formed on the substrate 108 may be a semiconductor material comprising compounds (e.g., GaN compounds) of at least one atom from the first precursor gas (e.g., Ga) and at least one atom from the second precursor gas (e.g. N). Portions of the first and second precursor gases that do not form a material on the substrate (e.g., Cl and H, such as in the form of HCl) may be flowed out of the chamber along with the purge gas(es). Using the gas injector 100 including one or more of the middle plate 104, the weld 146, and the plurality of precursor gas flow channels 142, as described above, may enable a reduced likelihood of formation of leaks, an improved uniformity of thickness of the material formed on the substrate, a wider area of the substrate across which the first precursor gas may flow, and/or an increased efficiency in precursor gas consumption.

The example embodiments of the disclosure described above do not limit the scope of the invention, since these embodiments are merely examples of embodiments of the invention, which is defined by the appended claims and their legal equivalents. Any equivalent embodiments are intended to be within the scope of this invention. Indeed, various modifications of the disclosure, in addition to those shown and described herein, such as alternative useful combinations of the elements described, may become apparent to those skilled in the art from the description. Such modifications and embodiments are also intended to fall within the scope of the appended claims.

1. A gas injector for a chemical deposition chamber, the gas injector comprising:
a base plate;
a middle plate positioned over the base plate; and
a top plate positioned over the middle plate on a side thereof opposite the base plate, wherein the base plate, the middle plate, and the top plate are configured to flow a purge gas between the base plate and the middle plate and to flow a precursor gas between the middle plate and the top plate.

2. The gas injector of claim 1, wherein the middle plate comprises one or more purge gas flow channels formed in a bottom surface thereof for flowing the purge gas from a purge gas inlet to an outlet side of the middle plate.

3. The gas injector of claim 1, wherein the middle plate comprises a plurality of precursor gas flow channels formed in an upper surface thereof for flowing the precursor gas from a precursor gas inlet to an outlet side of the middle plate.

4. The gas injector of claim 3, wherein each precursor gas flow channel comprises a relatively narrow inlet portion, a relatively wide outlet portion, and a diverging intermediate portion between the inlet portion and the outlet portion.

5. The gas injector of claim 1, further comprising a weld formed along at least one peripheral outer edge of the middle plate and of the top plate to couple the middle plate to the top plate.

6. The gas injector of claim 5, wherein the weld is configured to separate flow of the precursor gas between the middle plate and the top plate from flow of the purge gas between the base plate and the middle plate.

7. The gas injector of claim 5, wherein the weld is formed at least substantially continuously along all the peripheral outer edges of the middle plate and top plate with the exception of along outlet sides of the middle plate and top plate.

8. The gas injector of claim 1, wherein the base plate comprises a purge gas inlet extending therethrough and a hole extending therethrough, the hole sized and configured to receive a precursor gas inlet stem of the middle plate.

9. The gas injector of claim 1, wherein the base plate, middle plate, and top plate are each at least substantially comprised of quartz.

10. A method of forming a material on a substrate, the method comprising:
flowing a first precursor gas between a middle plate and a top plate of a gas injector;
flowing a purge gas between a base plate and the middle plate of the gas injector; and
flowing the first precursor gas out of the gas injector and toward a substrate positioned proximate the gas injector.

11. The method of claim 10, further comprising: flowing a second precursor gas along an upper surface of the top plate opposite the first precursor gas; and reacting the first precursor gas and the second precursor gas to form a material on the substrate.

12. The method of claim 10, wherein flowing a first precursor gas between a middle plate and a top plate of a gas injector comprises flowing the first precursor gas through a plurality of precursor gas flow channels formed in an upper surface of the middle plate.

13. The method of claim 10, wherein flowing a purge gas between a base plate and the middle plate of the gas injector comprises flowing the purge gas through at least one purge gas flow channel formed in a bottom surface of the middle plate.

14. The method of claim 10, further comprising inhibiting the first precursor gas from flowing into a flow path of the purge gas with a weld formed along peripheral outer edges of the middle plate and at least partially between the middle plate and the top plate.

15. A gas injector for a chemical deposition chamber, the gas injector comprising:
a precursor gas inlet;
at least one lateral precursor gas flow channel in fluid communication with the precursor gas inlet;
and a plurality of precursor gas flow channels in fluid communication with the at least one lateral precursor gas flow channel, the plurality of precursor gas flow channels extending from the at least one lateral precursor gas flow channel to an outlet of the gas injector.

16. The gas injector of claim 15, wherein the outlet of the gas injector comprises a semicircular surface.

17. The gas injector of claim 15, wherein each of the plurality of precursor gas flow channels comprises a relatively narrow inlet portion, a relatively wide outlet portion, and a diverging intermediate portion between the inlet portion and the outlet portion.

18. The gas injector of claim 15, wherein the plurality of precursor gas flow channels comprises eight precursor gas flow channels.
